(19) United States
(12) Patent Application Publication
(10) Pub. No.: US 2002/0159864 A1
(43) Pub. Date: Oct. 31, 2002

(54) Triple chamber load lock

(75) Inventor: Robert B. Lowrance, Los Gatos, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/972,562

(22) Filed: Oct. 5, 2001

Related U.S. Application Data
(60) Provisional application No. 60/287,322, filed on Apr. 30, 2001.

(51) Int. Cl. C23C 16/00

(52) U.S. Cl. 414/217; 118/719; 414/939

(57) ABSTRACT

A method and apparatus for transferring substrates is provided. In one embodiment, an apparatus for transferring substrates includes a first evacuable chamber and a evacuable second chamber separated by a third chamber, and a first transfer mechanism. The first transfer mechanism is movable between a first position located in the first chamber and a second position located in the third chamber. The first transfer mechanism includes a first seal plate coupled to a second seal plate and one or more substrate holders. The seal plates provides vacuum seals on opposing sides of the first chamber thereby balancing a force required to hold the first transfer mechanism and seal the first chamber from the third chamber during transfer of substrates from the substrate holder.

This application claims benefit of U.S. Provisional Application No. 60/287,322, filed Apr. 30, 2001, which is hereby incorporated by reference in its entirety.

### BACKGROUND OF THE DISCLOSURE

1. Field of Invention

The embodiments of the invention generally relate to a method and apparatus for transferring substrates in a semiconductor processing system.

### BACKGROUND OF INVENTION

Semiconductor substrate processing is typically performed by subjecting a substrate to a plurality of sequential processes to create devices, conductors and insulators on the substrate. These processes are generally performed in a process chamber configured to perform a single step of the production process. In order to efficiently complete the entire sequence of processing steps, a number of process chambers are typically coupled to a central transfer chamber that houses a robot to facilitate transfer of the substrate between the surrounding process chambers. A semiconductor processing platform having this configuration is generally known as a cluster tool, examples of which are the families of CENTURA® and ENDURA® processing platforms available from Applied Materials, Inc., of Santa Clara, Calif.

Generally, a cluster tool consists of a central transfer chamber having a robot disposed therein. The transfer chamber is generally surrounded by one or more process chambers. The process chambers are generally utilized to sequentially process the substrate, for example, performing various processing steps such as etching, physical vapor deposition, chemical vapor deposition, ion implantation, lithography and the like. As the processes performed in the process chambers are generally performed at vacuum pressure, the transfer chamber is maintained at vacuum pressure as well to eliminate having to repeatedly pump down the process chamber for each substrate transfer. This is important as pumping down the transfer chamber may require as much as eight hours to reach operational vacuum levels.

Load lock chambers are generally used to facilitate transfer of substrates between the vacuum environment of the transfer chamber and an environment of a factory interface wherein substrates are stored in cassettes. The factory interface is typically at or near atmospheric pressure. The load lock chambers are selectively isolated from the factory interface and transfer chamber by slit valves. Generally, at least one slit valve is maintained in a closed position to prevent loss of vacuum in the transfer chamber during substrate transfer through the load lock. For example, an interface slit valve is opened while a chamber slit valve is closed to allow an interface robot to transfer substrates between the load lock chamber and the substrate storage cassettes disposed in the factory interface. After the substrate is loaded from the interface robot, both slit valves are closed as the load lock chamber is evacuated by a pump to a vacuum level substantially equal to that of the transfer chamber. The substrate in the evacuated load lock is passed into the transfer chamber by opening the chamber slit valve while the interface slit valve remains closed. Processed substrates are returned to the factory interface in the reverse manner, wherein load lock chamber is vented to substantially equalize the pressure between the load lock chamber and the factory interface.

There are generally two types of load lock chambers utilized to interface with the transfer chamber. A first type is known as a batch-type chamber. The batch-type chamber generally holds an entire substrate storage cassette within the chamber. The cassette is first loaded into the load lock chamber and the chamber is sealed and pumped down to an appropriate vacuum level. The chamber is then opened to the transfer chamber so that the robot within the transfer chamber may access any of the substrates and storage slots within the cassette until all of the substrates within the cassette have been processed. After all the substrates have been returned to the cassette, the load lock chamber is isolated from the transfer chamber to facilitate replacing the cassette with another cassette containing un-processed substrates. While the cassettes are being exchanged, the transfer robot typically draws substrates from a cassette disposed in a second load lock chamber coupled to the transfer chamber.

The use of batch-type load lock chambers is generally a robust and effective system for transferring substrates into the transfer chamber. However, due to the relatively large internal volume required to accommodate the entire substrate cassette, pump-down times are long and the associated pumping hardware is large and costly. Additionally, venting of the large internal volume increases the chance of particulate contamination and condensation on the substrates.

The second type of load lock chamber is known as a single substrate-type. Generally, the single substrate-type load lock chamber shuttles one processed and one unprocessed substrate therethrough each time the load lock chamber is pumped down. To maintain high system throughput, single substrate-type load lock chambers are typically used in tandem. This allows a first load lock chamber to exchange a substrate in the vacuum environment with the transfer chamber while a second load lock chamber exchanges a substrates in the ambient environment with the factory interface.

Since cluster tools often utilize more than one load lock to maintain high substrate transfer rates, the cost of ownership is more than if a single load lock chamber could be utilized. Moreover, if one of the load lock chambers could be eliminated, an additional process chamber could be utilized in the open facet of the transfer chamber, thus enhancing system throughput.

Therefore, there is a need for an improved load lock chamber.

### SUMMARY OF INVENTION

One aspect of the present invention generally provides a method and apparatus for transferring substrates. In one embodiment, an apparatus for transferring substrates includes a first evacuable chamber and a evacuable second chamber separated by a third chamber, and a first transfer mechanism. The first transfer mechanism is movable between a first position located in the first chamber and a second position located in the third chamber. The first transfer mechanism includes a first seal plate coupled to a second seal plate and one or more substrate holders. The seal plates provides vacuum seals on opposing sides of the first chamber thereby balancing a force required to hold the first transfer mechanism and seal the first chamber from the third chamber during venting, pump down and transfer of substrates from the substrate holder.

In another embodiment, the apparatus further comprises a second transfer mechanism. The second transfer mechanism includes a first seal plate coupled to a second seal plate and one or more substrate holders. The seal plates provides vacuum seals on opposing sides of the second chamber thereby balancing a force required to hold the second transfer mechanism and seal the second chamber from the third chamber during transfer of substrates from the substrate holder.

In another aspect, a method for transferring substrates is provided. In one embodiment, the method includes providing at least one substrate disposed on a first substrate transfer mechanism disposed in an intermediate region of a load lock chamber, transferring substrates disposed on the first substrate transfer mechanism between the intermediate region of the load lock chamber and a transfer chamber, the transfer chamber having a first pressure and one or more process chambers coupled thereto, moving substrates disposed on the first substrate transfer mechanism from the intermediate region to a first region of the load lock chamber, sealing the first region from the third region by a first seal plate of the first substrate transfer mechanism, applying a secondary vacuum force to the first substrate transfer mechanism to offset a primary vacuum force applied to the first seal plate by the first pressure, and venting the first region to about the second pressure.

### BRIEF DESCRIPTION OF DRAWINGS

The teachings of the present invention can readily be understood by considering the following detailed description in conjunction with the accompanying drawings in which:

FIG. 1 depicts a plan view of a substrate processing system that includes one embodiment of a load lock chamber of the invention;

FIG. 2 depicts a sectional view of one embodiment of a load lock chamber in a first position;

FIG. 3 depicts a sectional view of the load lock chamber of FIG. 2 in a second position;

FIG. 4 depicts a perspective view of one embodiment of a substrate holder;

FIG. 5 depicts a perspective view of one embodiment of a load lock chamber; and

FIG. 6 depicts another perspective view of the load lock chamber of FIG. 5.

To facilitate understanding, identical reference numerals have been used, wherever possible, to designate identical elements that are common to the figures.

### DETAILED DESCRIPTION OF INVENTION

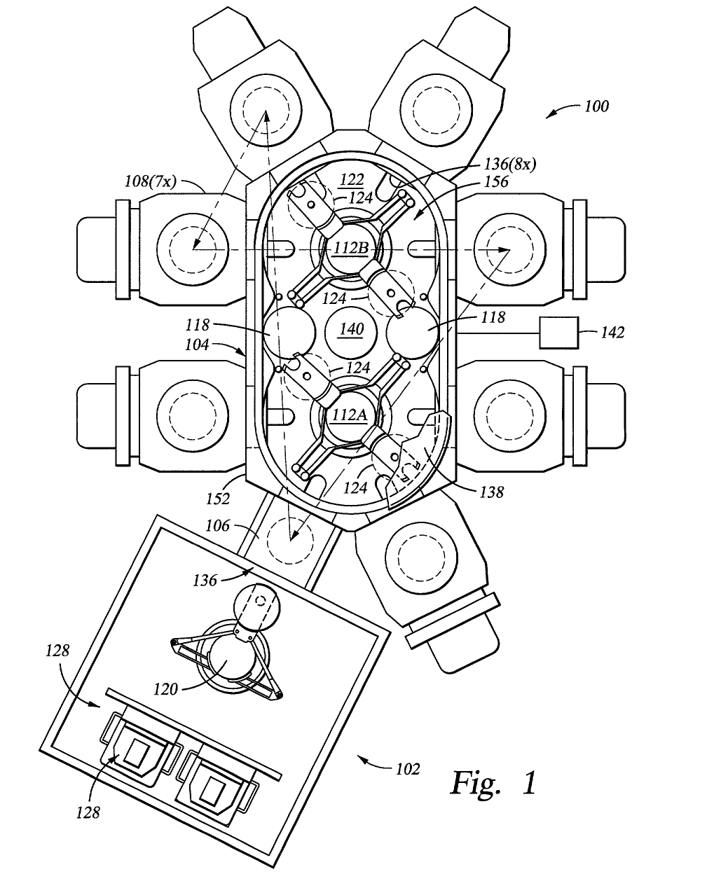

FIG. 1 depicts a processing system 100 that generally includes a factory interface 102, a load lock chamber 106, a plurality of process chambers 108 and a substrate transfer chamber 104. The transfer chamber 104 is generally used to transfer substrates 124 between a vacuum environment maintained in the transfer chamber 104 and a substantially ambient environment maintained in the factory interface 102. One example of a processing system that may be adapted to benefit from the invention is an ENDURA SL® processing platform, available from Applied Materials, Inc., of Santa Clara, Calif. Although the load lock chamber 106 is described disposed in the exemplary processing system 100 depicted in FIG. 1, the description is one of illustration and, accordingly, the load lock chamber 106 has utility wherever transfer of substrates between vacuum and ambient environments is desired.

The factory interface 102 generally includes an interface robot 120 and a plurality of bays 128. Each bay 128 is adapted to receive a substrate storage cassette 130. Generally, the factory interface 102 is coupled to the load lock chamber 106 through a port 136 that is positioned opposite the bays 128. The interface robot 120 includes a first gripper and a second gripper coupled thereto. Generally, each gripper may be an edge gripper, vacuum gripper or other substrate securing device used to hold the substrate 124 during transfer. The interface robot 120 is generally positioned between the port 136 and bays 128 to facilitate transfer of substrates between the cassettes 130 and the load lock 106. An example of one factory interface that may be adapted to benefit from the invention is described in U.S. patent application Ser. No. 09/161,970, filed Sep. 28, 1998 by Kroeker, which is hereby incorporated by reference in its entirety.

The transfer chamber 104 is generally fabricated from a single piece of material such as aluminum. The transfer chamber 104 generally includes side walls 150 and chamber bottom 156. A lid 138 is supported by the side walls 150 and, with the side wall 150 and chamber bottom 156, define an evacuable interior volume 122 therebetween. Substrates 124 are transferred between the process chambers 108 and load lock chambers 106 coupled to the exterior of the chamber 104 through the vacuum maintained within the volume 122.

At least one transfer robot is disposed in the transfer chamber 104 to facilitate transfer of substrates between the process chambers 108. In the illustrative embodiment depicted in FIG. 1, a first transfer robot 112A and a second transfer robot 112B are disposed in the interior volume 122 of the transfer chamber 104. The robots 112A, 112B may be of the dual or single blade variety. The robots 112A, 112B typically have a “frog-leg” linkage that is commonly used to transfer substrates in vacuum environments. The first robot 112A is generally disposed in an end of the transfer chamber 104 adjacent the load locks 106. The second robot 112B is disposed in an opposite end of the transfer chamber 104 such that each robot 112A, 112B services the adjacent process chambers 108.

One or more transfer platforms 118 are generally provided in the interior 122 of the chamber 104 to facilitate substrate transfer between robots 112A, 112B. For example, a substrate retrieved from one of the load locks 106 by the first robot 112A is set down on one of the platforms 118. After the first robot 112A is cleared from the platform 118 supporting the substrate 124, the second robot 112B retrieves the substrate from the platform 118. The second robot 112B may then transfer the substrate to one of the process chambers 108 serviced by the second robot 112B at that end of the transfer chamber 104.

The process chambers 108 are typically bolted to an exterior side 152 of the side walls 150 of the transfer chamber 104. Examples of process chambers 108 that may be utilized are etching chambers, physical vapor deposition chambers, chemical vapor deposition chambers, ion implantation chambers, lithography chambers and the like. Different process chambers 108 may be coupled to the transfer chamber 104 to provide a processing sequence necessary to form a predefined structure or feature upon the substrate's surface. An aperture (not shown) is disposed in the side wall between each process chamber 108 (or other chamber) to allow the substrate to be passed between the process chamber 108 and interior volume 122 of the transfer chamber 104. A slit valve 132 selectively seals each aperture to maintain isolation between the environments of the chambers 108, 104 between substrate transfers and during processing within the process chambers 108. One slit valve that may be used to advantage is described in U.S. Pat. No. 5,226,632, issued Jul. 13, 1993 to Tepman, et al., and is hereby incorporated by reference in its entirety.

Generally, a pumping system 142 is coupled to the transfer chamber 104 to evacuate and maintain the chamber at a predetermined vacuum level. Typically, a pumping port 140 is disposed in the chamber bottom 156 to fluidly couple the interior volume 122 to the pumping system 142. The pumping system 142 may include one or more pumps such as a roughing pump, a turbomolecular pump or a cryogenic pump.

The load lock chamber 106 is generally coupled between the factory interface 102 and the transfer chamber 104. The load lock chamber 106 is generally used to facilitate transfer of the substrates 124 between the transfer chamber 104 and the factory interface 102 rapidly without loss of vacuum within the transfer chamber.

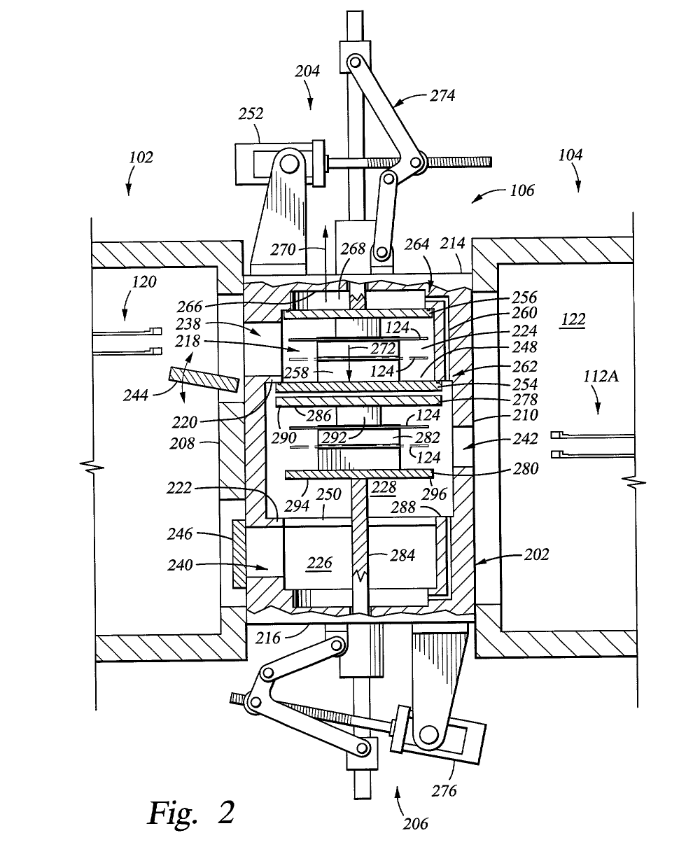

FIG. 2 depicts one embodiment of the load lock chamber 106. The load lock chamber 106 generally comprises a chamber body 202, a first substrate transfer mechanism 204 and a second substrate transfer mechanism 206. The chamber body 202 is preferably fabricated from a single body of material such as aluminum. The chamber body 202 includes a first side wall 208, a second side wall 210, lateral walls 212A and 212B, a top 214 and a bottom 216 that define a chamber volume 218. A first interior wall 220 is disposed between the first side wall 208 and the second side wall 210. A first region 224 is defined between the first interior wall 220 and the top 214 of the chamber body 202. A second interior wall 222 is disposed between the first side wall 208 and the second side wall 210. The second interior wall 222 is positioned between the first interior side wall 220 and the bottom 216 of the chamber body 202. A second region 226 is defined between the second interior wall 222 and the bottom 216 of the chamber body 202. A third region 228 is defined between the first interior wall 220 and the second interior wall 222.

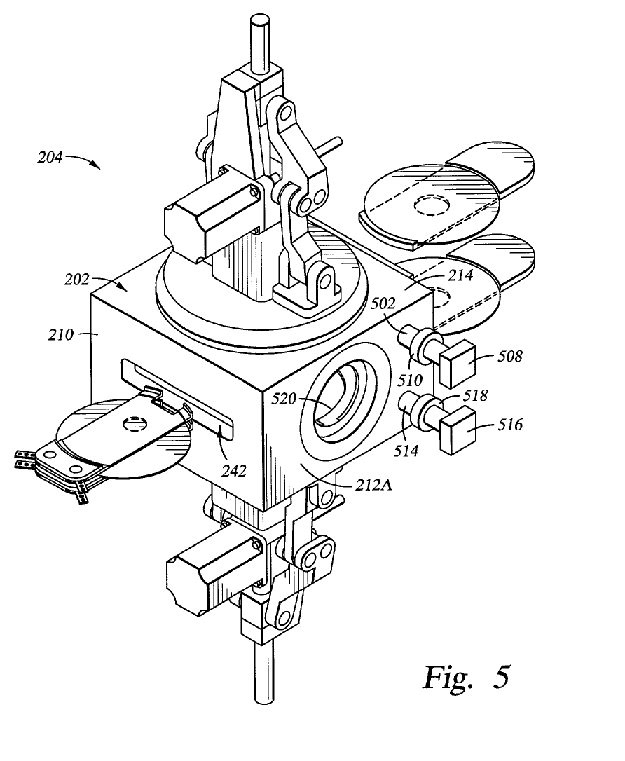

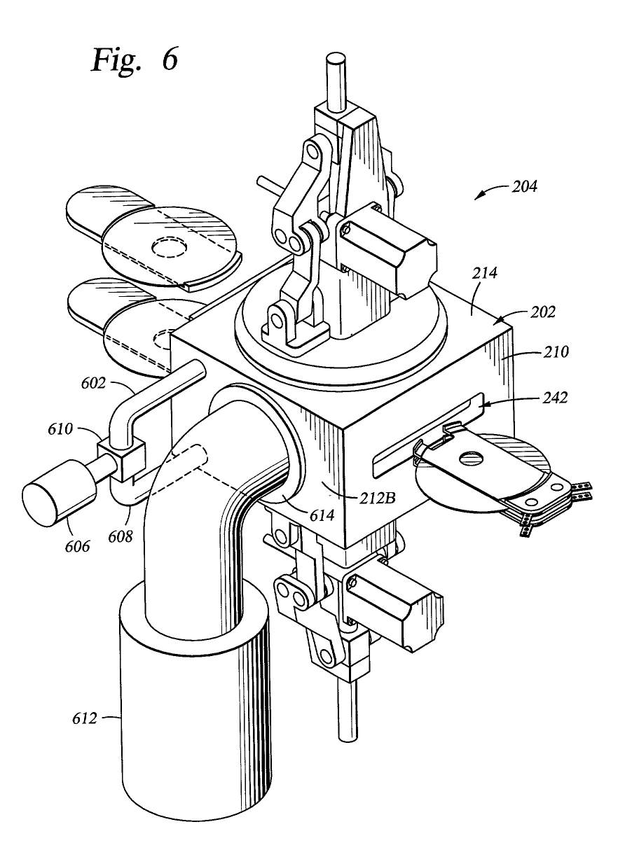

FIGS. 5 and 6 depict one embodiment of pressure control for both the first and second regions 224, 226. Typically, both the first and second regions 224, 226 have separate pressure control systems used to evacuate and vent the regions. Generally, the first region 224 is coupled by a first vent passage 502 to the atmosphere outside the load lock chamber 204 (see FIG. 5). A first pump passage 602 couples the first region 224 to a pumping system 604 (see FIG. 6). Typically, the vent passage 502 and the pump passage 602 are positioned at opposing ends of the first region 224 to induce laminar flow within the region during venting and evacuation to minimize particulate contamination while minimized substrate motion.

In one embodiment, the vent passage 502 is disposed in lateral wall 212A and coupled to a high efficiency air filter 508 such as available from Camfil-Farr, of Riverdale, N.J. A shut-off valve 510 is disposed between the filter 508 and the vent passage 502 to provide vacuum isolation within the region 224. Optionally, a window 520 may also be disposed in the lateral wall 212A to allow viewing of the interior of the load lock 204.

In one embodiment, the pump passage 602 is disposed on lateral wall 212B and coupled to a point-of-use pump 606 such as available from Alcatel, headquartered in Paris, France. The point-of-use pump 606 typically is positioned within three feet of the load lock 106 and has low vibration generation as not to disturb the substrates 124 positioned within the load lock chamber 106. Additionally, the pump's proximity to the load lock 106 promoting pump-down efficiency and time by minimizing the fluid path between the chamber 106 and pump 606.

The second region 226 is coupled by a second vent passage 514 to the atmosphere outside the load lock chamber 106. A second pump passage 608 is disposed on lateral wall 212B and couples the second region 226 to the pumping system 604. Generally, a diverter valve 610 allows for both passages 602, 608 to utilize a single pumping system 604. Optionally, each region 224, 226 may utilize a dedicated pump. Typically, the second vent passage 608 and the pump passage 516 are positioned at opposing ends of the second region 226.

In one embodiment, the second vent passage 514 is disposed in lateral wall 212A and is coupled to a high efficiency air filter 516. A shut-off valve 518 is disposed between the filter 516 and the vent passage 514 to provide vacuum isolation within the second region 226.

Optionally, a cryogenic pump 612 or other vacuum pump may be coupled to the third region 228 via a port 614 disposed in the lateral wall 212B. The pump 612 allows for additional pumping and pressure control within the third region 228.

Returning to FIG. 2, a first loading port 238 is disposed in one of the walls of the chamber body 202 to allow substrates 124 to be transferred between the first region 224 of the load lock 106 and the factory interface 102. A slit valve 244 selectively seals the first loading port 238 to isolate the load lock 106 from the factory interface 102. One slit valve that may be used to advantage is described in U.S. Pat. No. 5,226,632, issued Jul. 13, 1993 to Tepman et al., which is hereby incorporated by reference in its entirety.

A second loading port 240 is disposed in one of the walls of the chamber body 202 to allow substrates 124 to be transferred between the second region 226 of the load lock 106 and the factory interface 102. A slit valve 246 selectively seals the second loading port 240 to isolate the load lock 106 from the factory interface 102. Although the first loading port 238 and the second loading port 240 are typically disposed on the first side wall 208 of the load lock chamber 106, the ports 238, 240 may be both disposed on another wall or each on different walls of the chamber body 202.

A third loading port 242 is disposed in one of the walls of the chamber body 202 to allow substrates to be transferred between the load lock 106 and the transfer chamber 104. The third loading port 242 is generally disposed between the first interior wall 220 and the second interior wall 222 to allow fluid communication between the third region 228 of the load lock 106 and the transfer chamber 104. Although the third loading port 242 is typically disposed on the second wall 210 of the load lock chamber 106 opposite the first and the second loading ports 238, 240, the third loading port 242 may be disposed on any of the walls comprising the chamber body 202. As the third loading port 242 remains open to the transfer chamber 104 (i.e., there is no slit valve therebetween) the vacuum environment maintained in the transfer chamber 104 extends into the third region 228. Optionally, a slit valve (not shown) may be disposed between the third loading port 242 and the transfer chamber 104 to selectively seal the third region 228 and allow additional pump down of the third region 228 of the load lock 106.

A first aperture 248 is disposed in the first interior wall 220 to allow fluid communication between the first and the third regions 224, 228 of the chamber body 202. Similarly, a second aperture 250 is disposed in the second interior wall 222 to allow fluid communication between the second and the third regions 226, 228 of the chamber body 202.

In one embodiment, the first substrate transfer mechanism 204 generally includes a first actuator 252, a first seal plate 254, a second seal plate 256 and a substrate holder 258. The first substrate transfer mechanism 204 is generally moved between a first position (as depicted in FIG. 2) and a second position by the first actuator 252. In the first position, the substrate holder 258 is positioned in the first region 224 aligned with the first loading port 238. In the first position, the interface 120 robot may exchange substrates 124 through the first loading port 238 when the slit valve 244 is opened.

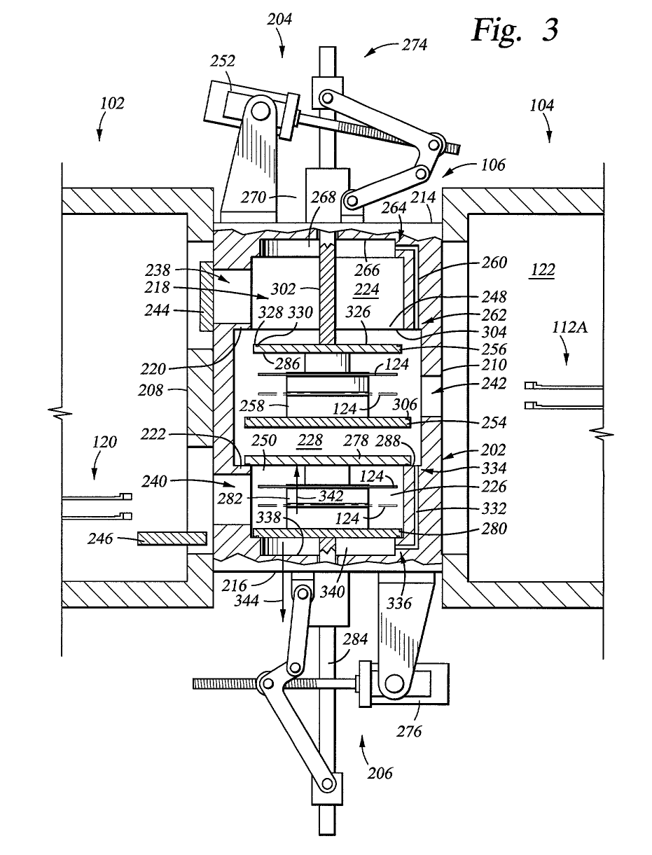

FIG. 3 depicts the first substrate transfer mechanism 204 in a second position. In the second position, the substrate holder 258 is positioned in the third region 228 aligned with the third loading port 242. In the second position, the transfer robot 112 disposed in the transfer chamber 104 may exchange substrates 124 through the third loading port 242.

The first actuator 252 is generally positioned exterior to the load lock chamber 106 and coupled to the second seal plate 256 by a shaft 302. The first actuator 252 may be a pneumatic cylinder, a hydraulic cylinder, lead screw, cam or other motion device configured to provide linear motion to the second seal plate 256.

The first seal plate 254 is generally cylindrical in form and includes sealing surface 308. The first seal plate 254 is generally greater in diameter than the first aperture 248 such that when the first substrate transfer mechanism 204 is in the first position, the sealing surface 308 seats against a lower side 304 of the first interior wall 220 to provide a vacuum seal between the first region 224 and the third region 228 as depicted in FIG. 1. The first seal plate 254 typically includes a seal 306 disposed on or in the sealing surface 308. The seal 306 may comprise a gasket, o-ring, lip seal or the like that provides a reliable vacuum seal between the first seal plate 254 and the first interior wall 220. Alternative geometric configurations for the first aperture 248 and first seal plate 254 may be utilized as long as a vacuum seal is established between the first seal plate 254 and the first interior wall 220 when the first substrate transfer mechanism is in the first position.

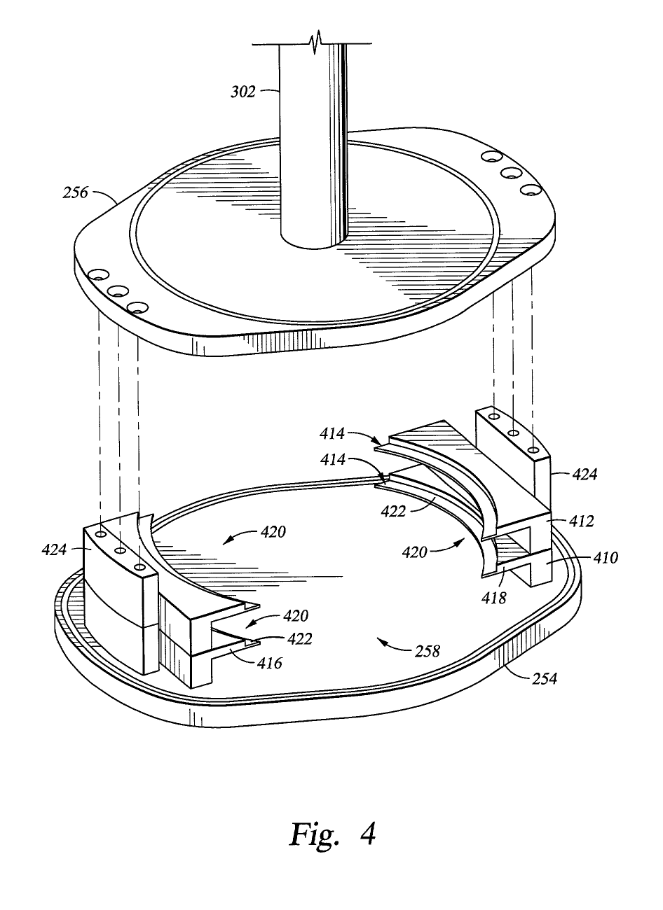

FIG. 4 depicts one embodiment of the substrate holder 258. Generally, the substrate holder 258 includes at least a first substrate holder 410 coupled to the first seal plate 254. A second substrate holder 412 preferably is concentrically coupled to (i.e., stacked on top of the first substrate holder 410. Each substrate holder 410, 412 is configured to retain one substrate 124. Optionally, additional substrate holders may be stacked on the second substrate holder 412 to retain a plurality of substrates. Alternatively, the first substrate holder 410 may be configured to accept a substrate storage cassette 130.

In one embodiment, each substrate holder 410, 412 comprises a pair of substrate support hoops 414. Each hoop includes a first member 416 and a second member 418 that are coupled to the first seal plate 254. Each member 416, 418 may have a “L-shaped” configuration, or be spaced from the first seal plate by a standoff. Each member 416, 418 includes a curved inner portion 420 that has a lip 422 extending radially inwards therefrom. The curved inner portion 420 is generally configured to allow the substrate 124 to pass therebetween and rest on the lip 422. The curved inner portion 420 captures the substrate 124 therebetween, thus preventing the substrate 124 from falling off the lip 422.

The pair of tabs 416, 418 comprising each substrate support hoop 414 is disposed in a spaced apart relation to allow the transfer or factory interface robot 112A, 120 to pass therebetween when retrieving and depositing substrates on the substrate holders 258.

A pair of stanchions 424 generally supports the second seal plate 256 above the first seal plate 254. Typically, the stanchions 424 are positioned outward of the substrate holders 258 to allow the substrates 124 to be disposed on the substrate holders 258 disposed between the seal plates 254, 256.

The second seal plate 256 is coupled to the first seal plate 254 by the stanchions 410. Generally, the second seal plate 256 is generally smaller in diameter (or area when the seal plates are configured in non-circular geometry) than the first seal plate 254. The second seal plate 256 is additionally smaller in diameter than the first aperture 248, thus allowing the second seal plate 256 to pass through the first aperture 248 as the first substrate transfer mechanism moves between the first and the second position.

Referring back to FIG. 3, in one embodiment, the second seal plate 256 includes a sealing surface 326 on a side 328 of the second seal plate 256 facing away from the first seal plate 254. The second seal plate 256 typically includes a seal 330 disposed on or in the sealing surface 326. The seal 330 may comprise a gasket, o-ring, lip seal or the like to provide a reliable vacuum seal between the second seal plate 256 and the top 214 of the chamber body 202 when the first substrate transfer mechanism 204 is in the first position.

Referring back to FIG. 2, a passage 260 is disposed in the chamber body 202 that has a first end 262 in communication with the third region 228 and a second end 264 disposed in the top 214 of the chamber body 202. Typically, the first end 262 is disposed in the first interior wall 220 radially outward of the interface between the seal 306 of the first seal plate 254 and the first interior wall 220. Alternatively, the first end 262 may be disposed in other areas of the chamber body 202 that maintain fluid communication with the third region 228 of the load lock chamber 106 regardless of the position of the first transfer mechanism 204.

The second end 264 is disposed in the top 214 of the chamber body 202 inwards of the interface between the seal 330 of the second seal plate 256 the top 214 of the chamber body 202 when the first substrate transfer mechanism 204 is in the second position. The second end 264 of the passage 260 is in communication with a plenum 268 disposed proximate the top 214 of the chamber body 202. Optionally, a counter bore 266 may be disposed in the top 214 of the chamber body 202 in communication with the passage 260 to define the plenum 268 between the second seal plate 256 and the top 214 of the chamber body 202.

When the first transfer device 204 is in the first position, the first seal plate 254 creates a vacuum seal between the first region 224 and the third region 228. Additionally, the second seal plate 256 creates a vacuum seal between the second seal plate 256 and the top 214 of the chamber body 202. As the passage 260 allows a vacuum to be established between the second seal plate 256 and the top 214 of the chamber body 202. Thus, as the first region 224 is vented to allow the atmosphere within the first region 224 to substantially equal the atmosphere of the factory interface 102, a first vacuum force 270 is generated on the second seal plate 256 while a second vacuum force 272 is generated on the first seal plate 254. The difference in the vacuum forces 270, 272 is generally proportional to the ratio of areas within the contact areas the respected seal area of the seal plates 254, 256 (as defined by the seals 306, 330). As the second vacuum force 272 opposes the first vacuum force 270, the net force required to maintain the first transfer mechanism 204 in the first position without compromising the vacuum integrity of the seals 306, 330 is substantially reduced as compared to conventional designs. Thus, a force required by the first actuator 252 to move and seal the first transfer mechanism 204 is accordingly minimized. Optionally, the first actuator 254 may be coupled to the second seal plate 256 by an over-center linkage 274 that allows the seal plates 254, 256 (i.e., the first transfer mechanism 204) to be locked in a predetermined position, preferably in the first position so that vacuum integrity of the transfer chamber 104 is maintained even if the first actuator 254 loses power while in the first position.

When the first transfer mechanism 204 is disposed in the second position, both seal plates 254, 256 are positioned in the third region 228. The spacing between the first interior wall 220 and the second interior wall 222 allows the substrate holders 258 to be positioned adjacent the third loading port 242 to allow access to the substrates 124 by the transfer robot 112A. Although second seal plate 256 is not required to pass through the first aperture 248 into the third region 228, having the second seal plate 256 move at least partially through the first aperture 248 allows the overall distance between the top 214 and the bottom 216 of the chamber body 252 to be minimized. Thus, minimizing the distance between the first seal plate 254 and the second seal plate 256 reduces pump down time.

The second transfer mechanism 206 is generally configured similar to the first transfer mechanism 204. In one embodiment, the second substrate transfer mechanism 206 generally includes a second actuator 276, a first seal plate 278, a second seal plate 280 and a substrate holder 282. The second substrate transfer mechanism 206 is generally moved between a first position and a second position by the second actuator 276. In the second position shown in FIG. 2, the substrate holder 282 is positioned in the third region 228 aligned with the third loading port 242. In the second position, the transfer robot 112A disposed in the transfer chamber 104 may exchange substrates 124 held in the second substrate transfer mechanism 206 through the third loading port 242.

In the first position shown in FIG. 3, the substrate holder 282 is positioned in the second region 226 aligned with the second loading port 240. In the first position, the factory interface robot 120 may exchange substrates 124 through the second loading port 240 when the slit valve 246 is opened.

The second actuator 276 is generally positioned exterior to the load lock chamber 106. Typically, the second actuator 276 controlling the movement of the second substrate transfer mechanism 206 is positioned on the opposite side of the chamber body 202 than the first actuator 252 that controls the first substrate transfer mechanism 204. The second substrate transfer mechanism 206 is coupled to the second seal plate 280 by a shaft 284 that passages through the bottom 216 of the chamber body 202. A dynamic seal or bellows (not shown) prevents fluid (i.e., gas) passage through the bottom 216 of the chamber body 202 around the shaft 284. A similar seal (also not shown) is disposed in the top 214 of the chamber body 202. The actuator 276 and its connection to the transfer mechanism 206 is similarly configured to the first actuator 252.

Referring back to FIG. 2, the first seal plate 278 is generally cylindrical in form and includes sealing surface 286. The first seal plate 278 is generally larger than the second aperture 250 such that when the second substrate transfer mechanism 206 is in the second position, the sealing surface seats against an upper side 288 of the second interior wall 222 to provide a vacuum seal between the second region 226 and the third region 228. The first seal plate 278 typically includes a seal 290 disposed on or in the sealing surface 286. The seal 290 may comprise a gasket, o-ring, lip seal or the like that provides a reliable vacuum seal between the first seal plate 278 and the second interior wall 222. Alternative configurations for the second aperture 250 and first seal plate 278 may be utilized as long as the vacuum seal is established between the first seal plate 278 and the second interior wall 222 when the second substrate transfer mechanism 206 is in the second position.

Generally, the substrate holder 282 is coupled to the second seal plate 280. The substrate holder 282 preferably is configured similarly to the substrate holder 258 described above.

A pair of stanchions 292 generally supports the first seal plate 278 above the second seal plate 280. Typically, the stanchions 292 are positioned outward of the substrate holder 282 to allow the substrates 124 to be disposed on the substrate holder 282 between the seal plates 278, 280 by the robots 112A, 130.

The second seal plate 280 is coupled to the first seal plate 278 by the stanchions 292. Generally, the second seal plate 280 is generally smaller in diameter (or area when the seal plates are configured in non-circular geometry) than the first seal plate 278. The second seal plate 280 is additionally smaller in diameter than the second aperture 250, thus allowing the second seal plate 280 to pass through the second aperture 250 as the second substrate transfer mechanism 206 moves between the first and the second position.

In one embodiment, the second seal plate 280 includes a sealing surface 294 on a side of the second seal plate 280 facing away from the first seal plate 278. The second seal plate 280 typically includes a seal 296 disposed on or in the sealing surface 294. The seal 296 may comprise a gasket, o-ring, lip seal or the like to provide a reliable vacuum seal between the second seal plate 280 and the bottom of the chamber body 202.

Referring to FIG. 3, a passage is disposed in the chamber body 202 that has a first end 334 in communication with the third region 228 and a second end 336 disposed in the bottom 216 of the chamber body 202. Typically, the first end 334 is disposed in the second interior wall 222 radially outward of the interface between the seal 290 of the first seal plate 278 and the second interior wall 222. Alternatively, the first end 334 may be disposed in other areas of the chamber body 202 that maintain fluid communication with the third region 228 of the chamber body 202.

The second end 336 is disposed in the bottom 216 of the chamber body 202 inwards of the interface between the seal 296 of the second seal plate 280 the bottom 216 of the chamber body 202. Optionally, a counter bore 338 may be disposed in the bottom 216 of the chamber body 202 in communication with the passage 332 to define a plenum 240 between the second seal plate 280 and the bottom of the chamber body 202.

When the second transfer device 206 is in the first position, the first seal plate 278 creates a vacuum seal between the second region 226 and the third region 228. Additionally, the second seal plate 280 creates a vacuum seal between the second seal plate 280 and the bottom of the chamber body 202. As the passage 332 allows a vacuum to be established between the second seal plate 280 and the bottom 216 of the chamber body 202. Thus, as the second region 226 is vented to allow the atmosphere within the second region 226 to substantially equal the atmosphere of the factory interface 102, a first vacuum force 342 generated on the first seal plate 278 while a second vacuum force 344 is generated on the second seal plate 280. The difference in the vacuum forces is generally proportional to the areas defined within the area of the seal plates 278, 280 bounded by the respected seals 290, 296. As the second vacuum force 344 opposes the first vacuum forces 342, the net force required to maintain the second substrate transfer mechanism 206 in the second position without compromising the vacuum integrity of the seals 290, 296 is substantially reduced. Thus, a force required by the second actuator 276 to move and seal the second substrate transfer mechanism 206 is reduced over conventional designs.

Referring back to FIG. 2, when the second substrate transfer mechanism 206 is disposed in the first position, both seal plates 278, 280 are positioned in the third region 228. Although second seal plate 280 is not required to pass through the second aperture 280 into the third region 228, having the second seal plate 280 move at least partially through the second aperture 250 allows the overall distance between the top 214 and the bottom 216 of the chamber body 206 to be minimized. Thus, minimizing the distance between the first seal plate 278 and the second seal plate 280 reduces pump down time.

Alternatively, the load lock chamber 106 may be described as having a first chamber, a second chamber and a third chamber. The first chamber is defined by the first region 224. The second chamber is defined by the second region 226 and the third chamber is defined by the third region 228. The first substrate transfer mechanism 204 moves the substrates between the first and third chambers while the second substrate transfer mechanism 206 moves the substrates between the second and third chambers.

Referring to FIGS. 2 and 3, in one mode of operation, the load lock 106 shuttles substrates utilizing both the first substrate transfer mechanism 204 and the second substrate transfer mechanism 206 to maximize substrate throughput into and out of the transfer chamber 104. Moreover, the load lock chamber 106 only requires one position on the exterior of the transfer chamber 104, thus allowing an additional process chambers 108 to be employed as compared to systems having two conventional load lock chambers.

Generally, in operation, the slit valve 244 is opened with the first substrate transfer mechanism 204 in the first position and the first region 224 vented to substantially atmospheric pressure. The factory interface robot 120 transfers an unprocessed substrate from one of the cassettes 130 to the second substrate holder 412. A processed substrate is removed from the first substrate holder 410 by the factory interface robot 120 and returned to one of the cassettes 130. After completion of the substrate transfer, the slit valve 144 is closed and the first region is pumped down to the pressure substantially equal to the pressure of the transfer chamber 104.

While the first substrate transfer mechanism 204 is in the first position, the second substrate transfer mechanism 206 is in the second position. A processed substrate is disposed in the first substrate holder by one blade of the transfer robot 112A while a second blade of the transfer robot 112A retrieves an unprocessed substrate for processing in one or more of the process chambers 108 circumscribing the transfer chamber 104. After substrate transfer is completed, the second substrate transfer mechanism 206 is moved to the second region 226 wherein the first seal plate 278 seals the second region 226 from the third region 228. The vent is opened in the second region to allow the pressure in the second region to rise to substantially match the pressure in the factory interface. Once, the pressures are matched, the slit valve 246 is opened to allow the second substrate transfer mechanism 206 to interface with the factory interface robot 120 as described above with reference to the first substrate transfer mechanism 204.

After the second substrate transfer mechanism 206 has cleared the third region 228, the first substrate transfer mechanism 204 is moved from the first region 224 to the third region 228. The transfer robot 112A then interfaces with the first substrate transfer mechanism 204 as described above with reference to the second substrate transfer mechanism 206.

Although the teachings of the present invention that have been shown and described in detail herein, those skilled in the art can readily devise other varied embodiments that still incorporate the teachings and do not depart from the scope and spirit of the invention.

What is claimed is:

1. Apparatus for transferring substrates comprising:
a first chamber having an evacuable volume;
a second chamber fluidly coupled to the first chamber;
a first substrate transfer mechanism movable between a first position and a second position, the first substrate transfer mechanism comprising:
a first plate movable between the first chamber and the second chamber, the first plate providing a vacuum seal between the first chamber and the second chamber when the first substrate transfer mechanism is in the first position;
a second plate coupled to the first plate, the second plate providing a vacuum seal between the second plate and a portion of the first chamber when in the first position; and
one or more substrate holder disposed between the first plate and the second plate.

2. The apparatus of claim 1 further comprising:
a third chamber fluidly coupled to the second chamber;
a second substrate transfer mechanism movable between a first position and a second position, the second substrate transfer mechanism comprising:
a first plate movable between the second chamber and the third chamber, the first plate providing a vacuum seal between the third chamber and the second chamber when the second substrate transfer mechanism is in the second position;
a second plate coupled to the first plate, the second plate providing a vacuum seal between the third chamber and the second plate when the substrate transfer mechanism is in the second position; and
one or more substrate holder disposed between the first plate and the second plate.

3. The apparatus of claim 1, wherein the substrate holder comprises:
a first substrate holder and a second substrate holder, the first substrate holder adapted to hold a first substrate concentrically to a second substrate held in the second substrate holder.

4. The apparatus of claim 3, wherein the first substrate holder further comprises:
a first member having a curved inner portion;
a second member having a curved inner portion;
a lip extending from each curved inner portion adapted to support the first substrate from opposite portions of a perimeter of the first substrate; and wherein the second substrate holder further comprises:
a third member coupled to first member, the third member having a curved inner portion concentric to the curved inner portion of the first member;
a fourth member coupled to second member, the third member having a curved inner portion concentric to the curved inner portion of the second member;
a lip extending from the curved inner portions of the third and the fourth members and adapted to support the second substrate from opposite portions of a perimeter of the second substrate.

5. The apparatus of claim 1, wherein an interior wall separates the first chamber from the second chamber, the interior wall having an aperture disposed therein fluidly coupling the first chamber and the second chamber, wherein the upper plate selectively seals the aperture.

6. The apparatus of claim 5, wherein a passage is disposed through the interior wall fluidly coupling a volume defined between the second plate and the first chamber.

7. The apparatus of claim 6, wherein the passage further comprises a port disposed in the interior wall and positioned radially outward of an interface between the first plate and the first interior wall.

8. The apparatus of claim 2, wherein the first chamber further comprises:
a port disposed adjacent the first chamber in a sidewall of the first chamber; and
a slit valve selectively sealing the port; and
wherein the second chamber further comprises:
an aperture disposed in a sidewall of the second chamber. The aperture positioned opposite the port disposed in the first chamber and the aperture open to the third chamber.

9. Apparatus for transferring substrates comprising:
a first chamber having an evacuable volume;
a second chamber having an evacuable volume;
a third chamber disposed between the first chamber and the second chamber;
a first substrate transfer mechanism movable between a first position and a second position, the first substrate transfer mechanism comprising:
a first plate movable between the first chamber and the third chamber, the first plate providing a vacuum seal between the first chamber and the third chamber when the first substrate transfer mechanism is in the first position;
a second plate coupled to the first plate, the second plate providing a vacuum seal between the second plate and a portion of the first chamber when in the first position; and
one or more substrate holder disposed between the first plate and the second plate.

10. The apparatus of claim 9 further comprising:
a second substrate transfer mechanism movable between a first position and a second position, the second substrate transfer mechanism comprising:
a first plate movable between the second chamber and the third chamber, the first plate providing a vacuum seal between the third chamber and the second chamber when the second substrate transfer mechanism is in the second position;
a second plate coupled to the first plate, the second plate providing a vacuum seal between the second chamber and the second plate when the substrate transfer mechanism is in the second position; and
one or more substrate holder disposed between the first plate and the second plate.

11. The apparatus of claim 9, wherein the substrate holder comprises:
a first substrate holder and a second substrate holder, the first substrate holder adapted to hold a first substrate concentrically to a second substrate held in the second substrate holder.

12. The apparatus of claim 11, wherein the first substrate holder further comprises:
a first member having a curved inner portion;
a second member having a curved inner portion;
a lip extending from each curved inner portion adapted to support the first substrate from opposite portions of a perimeter of the first substrate; and wherein the second substrate holder further comprises:
a third member coupled to first member, the third member having a curved inner portion concentric to the curved inner portion of the first member;
a fourth member coupled to second member, the third member having a curved inner portion concentric to the curved inner portion of the second member;
a lip extending from the curved inner portions of the third and the fourth members and adapted to support the second substrate from opposite portions of a perimeter of the second substrate.

13. The apparatus of claim 9, wherein a first interior wall separates the first chamber from the third chamber, the first interior wall having an aperture disposed therein fluidly coupling the first chamber and the third chamber, wherein the upper plate selectively seals the aperture.

14. The apparatus of claim 9, wherein a passage is disposed through a wall of the first chamber fluidly coupling a volume defined between the second plate and the chamber body with the third chamber.

15. The apparatus of claim 14, wherein the passage further comprises a port disposed in an interior wall disposed between the first and the second chambers, the port positioned radially outward of an interface between the first plate and the first interior wall.

16. The apparatus of claim 14, wherein the first chamber further comprises a top having a recess disposed therein, the recess selectively covered by the second plate and in fluid communication with the passage.

17. The apparatus of claim 10, wherein the first chamber further comprises:
a fist port disposed in a sidewall of the first chamber and selectively sealed by a first slit valve;
wherein the second chamber further comprises:
a second port disposed in a sidewall of the second chamber and selectively sealed by a second slit valve; and
an aperture disposed in a sidewall of the third chamber, the aperture positioned opposite the first and second ports.

18. The apparatus of claim 9, wherein the first chamber and the second chamber are oscillated between vacuum and ambient pressures; and the third chamber is maintain at a vacuum pressure.

19. The apparatus of claim 11 further comprising:
a first actuator coupled to the first substrate transfer mechanism; and
a second actuator coupled to the second substrate transfer mechanism and independently operable from the first substrate transfer mechanism.

20. Apparatus for transferring a substrate between a first environment having a first pressure and a second environment having a vacuum pressure, the apparatus comprising:
a chamber body having a first side wall, a second side wall, a top and a bottom defining a chamber volume therebetween;
a first interior wall disposed between the first side wall and the second side wall, the first interior wall having a first aperture disposed therein;
a first region defined between the first interior wall and the top of the chamber body, the first region being selectively isolatable from the first environment;
a second interior wall disposed between the first side wall and the second side wall, the first interior wall having a second aperture disposed therein;
a second region defined between the second interior wall and the bottom of the chamber body, the second region being selectively isolatable from the first environment;
a third region defined between the first interior wall and the second interior wall the third region having fluid communication with the second environment and begin selectively isolatable from the first and second regions;
a first substrate transfer mechanism moveable between the first and third regions, the first substrate transfer mechanism comprising:
a first plate;
a second plate coupled to the first plate;
a first substrate holder disposed between the first plate and the second plate; and
a second substrate holder disposed between the first substrate holder and the second plate; and
a second substrate transfer mechanism moveable between the second and third regions, the second substrate transfer mechanism comprising:
a first plate;
a second plate coupled to the first plate;
a first substrate holder disposed between the first plate and the second plate; and
a second substrate holder disposed between the first substrate holder and the second plate.

21. The apparatus of claim 20, wherein a force required to hold the first transfer mechanism in the first region is proportional to a ratio of sealing areas of the first plate and the second plate.

22. The apparatus of claim 20, wherein the first plate of the first transfer mechanism selectively seals the first aperture; and the first plate of the second transfer mechanism selectively seals the second aperture.

23. The apparatus of claim 20 further comprising:
a first slit valve disposed on the first wall of the chamber body and selectively sealing the first region from the first environment; and
a second valve disposed on the first wall of the chamber body and selectively sealing the second region from the first environment.

24. The apparatus of claim 20, wherein the chamber body further comprises an aperture disposed in the second sidewall allowing the third region of the chamber body to maintain fluid communication with the second environment.

25. The apparatus of claim 24, wherein the chamber body further comprises a passage disposed therein, the passage fluidly coupling the second environment to a recess disposed in the top of the chamber body.

26. The apparatus of claim 25, wherein the second plate selectively seals the recess from the first region.

27. The apparatus of claim 20 further comprising:
a first actuator coupled to the first substrate transfer mechanism by an over-center linkage; and
a second actuator coupled to the second substrate transfer mechanism by an over-center linkage.

28. Apparatus for transferring a substrate comprising:
a transfer chamber adapted to transfer substrate in a vacuum environment;
at least one robot disposed within the transfer chamber;
one or more processing chamber coupled to the transfer chamber; and
a first load lock chamber having an evacuable volume;
a second load lock chamber having an evacuable volume;
a third load lock chamber disposed between the first load lock chamber and the second load lock chamber, the third load lock chamber having an aperture fluidly coupling the third load lock chamber and the transfer chamber;
a first substrate transfer mechanism a first position and a second position, the first substrate transfer mechanism comprising:
a first plate movable between the first chamber and the third chamber, the first plate providing a vacuum seal between the first chamber and the third chamber when the first substrate transfer mechanism is in the first position;
a second plate coupled to the first plate, the second plate providing a vacuum seal between the second plate and first chamber when in the first position; and
one or more substrate holder disposed between the first plate and the second plate; and
a second substrate transfer mechanism a first position and a second position, the second substrate transfer mechanism comprising:
a first plate movable between the second chamber and the third chamber, the first plate providing a vacuum seal between the third chamber and the second chamber when the second substrate transfer mechanism is in the second position;
a second plate coupled to the first plate, the second plate providing a vacuum seal between the second chamber and the second plate when the substrate transfer mechanism is in the second position; and
one or more substrate holder disposed between the first plate and the second plate.

29. The apparatus of claim 28, wherein the substrate holder comprises:
a first substrate holder and a second substrate holder, the first substrate holder adapted to hold a first substrate concentrically to a second substrate held in the second substrate holder.

30. The apparatus of claim 29, wherein a first interior wall separates the first chamber from the third chamber, the first interior wall having an aperture disposed therein fluidly coupling the first chamber and the third chamber, wherein the upper plate selectively seals the aperture.

31. The apparatus of claim 29, wherein a passage fluidly couples a portion of the first chamber with the third chamber, the portion of the first chamber is selectively sealed from the third chamber by the second plate.

32. The apparatus of claim 29 wherein the first chamber and the second chamber are oscillated between vacuum and ambient pressures, and the third chamber is maintain at a pressure of the transfer chamber.

33. A method for transferring substrates between a first pressure and a second pressure comprising:
providing at least one substrate disposed on a first substrate transfer mechanism disposed in an intermediate region of a load lock chamber;
transferring substrates disposed on the first substrate transfer mechanism between the intermediate region of a load lock chamber and a transfer chamber, the transfer chamber having a first pressure and one or more process chambers coupled thereto;
moving substrates disposed on the first substrate transfer mechanism between the intermediate region and a first region of the load lock chamber;
sealing the first region from the third region by a first seal plate of the first substrate transfer mechanism;
applying a secondary vacuum force to the first substrate transfer mechanism to offset a primary vacuum force applied to the first seal plate by the first pressure;
venting the first region to about the second pressure.

34. The method of claim 33, wherein the step of applying a secondary vacuum force comprises:
placing a portion of a second seal plate of the first substrate transfer mechanism in fluid communication with the first pressure.

35. The method of claim 33, wherein the step of venting further comprises creating a flow of filtered air within the first chamber.

36. The method of claim 35, wherein the flow is substantially laminar.

37. The method of claim 33, wherein the step of transferring substrates further comprises:
passing a processed substrate to the first substrate transfer mechanism; and
passing an unprocessed substrate to the transfer chamber.

38. The method of claim 37, wherein the process substrate is held in a first holder on the first substrate transfer mechanism below a second holder that holds unprocessed substrates.

39. The method of claim 33 further comprising:
transferring substrates disposed on a second substrate transfer mechanism that is disposed in a second region of the load lock chamber;
sealing the second region from the second pressure;
substantially equalizing a pressure within the second region to that of the first pressure;
moving substrates disposed on the second substrate transfer mechanism between the second region and the intermediate region of the load lock chamber; and
transferring substrates disposed on a second substrate transfer mechanism between the third region of the load lock chamber and the transfer chamber.

40. A method for determining the location of a substrate positioned on a robot element subjected to changing thermal conditions, comprising:
sensing and storing a set of metrics of the substrate prior to a change in thermal conditions;
subjecting the robot element to changed thermal conditions;
sensing and storing a set of metrics of the substrate after the change in thermal conditions; and
resolving the position of the substrate resulting from thermal change of the robot element metrics.
